(19) United States
(12) Patent Application Publication
(10) Pub. No.: US 2024/0234669 A1
(43) Pub. Date: Jul. 11, 2024

(54) OPTOELECTRONIC LIGHTING DEVICE

(71) Applicant: ams-OSRAM International GmbH, Regensburg (DE)

(72) Inventors: Daniel Richter, Abbach (DE); Gunnar Petersen, Regensburg (DE)

(21) Appl. No.: 18/558,691

(22) PCT Filed: May 10, 2022
(86) PCT No.: PCT/EP2022/062692

§ 371 Date: Nov. 2, 2023

(30) Foreign Application Priority Data
May 12, 2021 (DE) 10 2021 112 359.3

(51) Int. Cl. H01L 33/64; H01L 33/50; H01L 33/60

(52) U.S. Cl. CPC H01L 33/644; H01L 33/505; H01L 33/60

(57) ABSTRACT

In embodiments, an optoelectronic lighting device includes at least one optoelectronic light source configured to generate light, at least one converter configured to generate converted light by converting the light and a thermally conductive substrate, wherein the converter is arranged on the substrate and the light source is arranged above the converter, wherein a mirror coating is arranged on a side of the light source facing away from the converter, wherein the mirror coating is configured to be transparent for the converted light and/or to reflect the light, wherein an upper side of the substrate, on which the converter is arranged, comprises a flat region and a rising region adjoining the flat region, and wherein the converter is located at least on the rising region.

### CROSS-REFERENCE TO RELATED APPLICATIONS

This patent application is a national phase filing under section 371 of PCT/EP2022/062692, filed May 10, 2022, which claims the priority of German patent application 10 2021 112 359.3, filed May 12, 2021, each of which is incorporated herein by reference in its entirety.

### TECHNICAL FIELD

The present invention relates to an optoelectronic lighting device comprising at least one optoelectronic light source for generating light, at least one converter for generating converted light by converting the light provided by the light source, and a substrate.

### SUMMARY

The invention relates in particular to an optoelectronic lighting device which comprises at least one optoelectronic light source for generating light, at least one converter for generating converted light by conversion of the light provided by the light source, and a substrate, in particular a thermally conductive substrate, the converter being arranged on the substrate for better heat dissipation and the light source being arranged above the converter or being arranged laterally next to the converter likewise on the substrate.

By improving the dissipation of heat from the converter, heat-related effects that cause deterioration of the conversion can be avoided or at least reduced. In particular, the effect of “thermal quenching” can be reduced or avoided. This effect causes the intensity of the converted light to decrease at higher pump powers, i.e., at a higher intensity of the light provided by the light source and correspondingly at higher currents through the light source. Due to the improved thermal connection of the converter, such a drop in intensity at higher currents through the light source can be avoided or at least reduced. Thus, higher light outputs can also be achieved.

A mirror coating, in particular in the form of a Bragg mirror, can be arranged above the light source, in particular on the upper side of the light source, whereby the mirror coating is transparent to the converted light and reflects the light generated by the light source. Unwanted upward radiation of the light provided by the light source can thus be avoided. In addition, the mirror coating can reflect the light provided by the light source into the converter. Since the mirror coating is transparent for the converted light, an upward radiation of the converted light can take place. In particular, the light source can also be transparent to the converted light. The sealing can also be realized in a classical way, for example by means of a mirror layer.

According to at least one embodiment of the invention, the term “transparent” or the term “transparency” may mean a transmittance of at least 50%, 60%, 70%, 80%, 90%, 95%, 98%, or 99% with respect to an incident light intensity.

According to at least one embodiment of the invention, the term “reflected” or the term “reflectivity” may mean a reflectivity of at least 50%, 60%, 70%, 80%, 90%, 95%, 98%, or 99% with respect to an incident light intensity.

The mirror coating can be formed as a layer that extends at least substantially over the entire length and width of the device. This can efficiently prevent light provided by the light source from escaping upwardly out of the device. Alternatively, the mirror coating may extend only over the entire top surface of the light source.

The light source may have overhead electrical contacts for power supply. The electrical contacts may be formed as planar contacts that run in a plane parallel to the top of the substrate. The electrical contacts may also be formed as a bonding wire. Since the electrical contacts are located at the top of the light source, the bottom of the light source can be located directly on the converter. If it is intended that the light source is arranged next to the converter, the underside of the light source can be arranged directly on the substrate, and good heat dissipation for the heat generated in the light source can be achieved via the substrate.

The device may comprise an encapsulation extending circumferentially around the converter and/or around the light source, wherein, preferably, the encapsulation reflects the converted light and/or the light provided by the light source. The encapsulation allows more of the light from the light source to be brought into the converter and thus converted. Further, for the converted light, the upward light output can be improved.

When the light source is arranged laterally next to the converter on the substrate, at least two converters can be provided and the light source can be arranged between the two converters. An efficient conversion of the light provided by the light source into converted light can thus be achieved.

An upper side of the substrate on which the converter is arranged may comprise a flat region and an ascending area adjoining the flat area, wherein the converter is arranged at least on the ascending area and preferably also on the flat area. Due to the rising region of the substrate, converted light can be reflected upwards in an improved manner and thus a higher light emission efficiency can be achieved at the upper side of the lighting device. The substrate may thereby comprise a high reflectivity for converted light and/or for light provided by the light source.

The light source can be arranged above the flat region and an upper side of the light source can face the rising area. Efficient exposure of the converter to light from the light source can thus be realized.

The top of the light source may be oriented perpendicular to the surface of the flat region of the substrate. The light source may have its bottom surface attached to a wall that is perpendicular to the flat region of the substrate. The wall may be, for example, a wall of a submount that may provide electrical connections for the light source. Preferably, the light source is formed as a flip chip.

The invention also relates to an optoelectronic lighting device which comprises at least one optoelectronic light source for generating light, at least one converter for generating converted light by converting the light from the light source, and a substrate, in particular a thermally conductive substrate, the light source being arranged laterally next to the converter and a light-conducting layer, in particular with a grating structure, being formed between the substrate and the light source in order to guide the light provided by the light source to the converter. Improved coupling in and/or coupling out can be achieved via the grating structure. The grating structure can be formed by trenches running parallel to each other, which are introduced into the light-conducting layer.

By means of the light conducting layer, the light generated by the light source can be directed to the converter in an efficient manner. As a result, an increased luminous efficiency of converted light can be achieved.

The light-conducting layer can be arranged on the substrate and the converter and the light source can be arranged on the light-conducting layer. A particularly compact arrangement can thus be realized.

According to at least one embodiment of the invention, at least two converters may be provided, and the light source may be arranged between the two converters, wherein an encapsulation is arranged between the light source and a respective converter, wherein, preferably, the encapsulation reflects the converted light and the light provided by the light source. An efficient conversion of the light provided by the light source into converted light can thereby be achieved.

The invention also relates to an optoelectronic lighting device which comprises at least one optoelectronic light source for generating light, at least one converter for generating converted light by converting the light from the light source, and a substrate, in particular a thermally conductive substrate, at least one heat-conducting layer for dissipating heat from the converter being provided above the converter, in particular directly above the converter. By means of the heat-conducting layer, efficient dissipation of the heat generated in the converter can be achieved. The heat conduction layer is preferably designed as a transparent layer, so that emission of converted light through the heat conduction layer upwards out of the device is possible.

The light source may be arranged on the substrate and the converter may be arranged above the light source. In particular, the converter may be disposed directly on the light source. The light source may also be arranged directly on the substrate. The substrate may thereby provide electrical contacts to which the electrical contacts of the light source may be connected. Preferably, the light source is designed as a flip chip so that both electrical contacts of the light source are located on the bottom side and can be directly connected to electrical contacts on the substrate.

In particular, the upper side of the light source can be flat, and the converter can be arranged directly on the flat upper side of the light source. Direct coupling of the light generated by the light source into the converter can thus be achieved.

An encapsulation may extend circumferentially around the light source and under the converter, the encapsulation reflecting the converted light and the light provided by the light source. This allows the light provided by the light source to be brought into the converter in an improved manner. In addition, the efficiency of radiating converted light upward can be improved.

The outer edge of the heat-conducting layer can be in thermal contact with a housing wall of the device. A buildup of heat in the heat-conducting layer can thus be avoided.

The invention also relates to an optoelectronic lighting device which comprises at least one optoelectronic light source for generating light, at least one converter for generating converted light by converting the light from the light source, and a substrate, in particular a thermally conductive substrate, one or more, in particular transparent, heat-conducting layers being arranged in the converter for dissipating heat from the converter. Improved dissipation of heat from the converter can be achieved by the heat-conducting layer. Undesirable thermal effects in the converter can therefore be avoided or at least reduced.

The invention also relates to an optoelectronic lighting device which comprises at least one optoelectronic light source for generating light, at least one converter for generating converted light by converting the light from the light source, and a substrate, in particular a thermally conductive substrate, at least one and preferably a plurality of heat-conducting elements, in particular non-transparent heat-conducting elements, being arranged in the converter for dissipating heat from the converter. The heat conducting elements also make it possible to avoid or at least reduce undesirable thermal effects in the converter.

A respective heat conducting element can project through the converter as seen in a height direction, the height direction being perpendicular to the top of the substrate. Efficient heat dissipation over the entire height of the converter can thus be achieved.

A respective heat conducting element may comprise a triangular cross-section. Due to a triangular cross-section of the heat conducting elements, a respective element is particularly suitable as a reflector for the light provided by the light source and/or for the converted light.

A respective heat conducting element can be designed as an elongated rod-shaped element. Such heat-conducting rods can be fully or partially immersed in the converter parallel to one another and spaced apart. In a structure consisting of converter and immersed heat-conducting rods, good heat dissipation can be achieved.

A respective heat conducting element may be made of a metal, such as copper, silver, or gold. A respective heat conducting element may be highly reflective for the light provided by the light source and/or for the converted light.

The converter can be designed as a converter plate with, for example, a rectangular cross-section. Converters are known per se, and have optically active materials that can convert light of a first wavelength into at least one other, second wavelength in a manner known per se, the second wavelength being greater than the first wavelength.

The light source can be an LED or an LED chip. LED stands for light emitting diode.

The light source can be an optoelectronic laser, such as a laser diode or a VCSEL. VCSEL stands for vertical cavity surface emitting laser. Such lasers are well known.

For example, the light source may emit blue light, which is converted by the converter into light of another color, such as red light or infrared light or white light. The term “light” in this context is not limited to the visible spectral range, but also includes electromagnetic radiation outside the visible range, such as infrared or ultraviolet light.

Features disclosed in combination with one embodiment herein may also be realized in another embodiment, even if not explicitly disclosed herein.

### BRIEF DESCRIPTION OF THE DRAWINGS

The invention is described in more detail below by way of example and with reference to the accompanying drawings.

FIG. 1 shows a side cutaway view of a variant of an optoelectronic lighting device according to the invention;

FIG. 2 shows a top view of the device of FIG. 1;

FIG. 3 shows a side cutaway view of a further variant of an optoelectronic lighting device according to the invention;

FIG. 4 shows a top view of the device of FIG. 3;

FIG. 5 shows a side cutaway view of a further variant of an optoelectronic lighting device according to the invention;

FIG. 6 shows a top view of the device of FIG. 5;

FIG. 7 shows a side cutaway view of a further variant of an optoelectronic lighting device according to the invention;

FIG. 8 shows a side cutaway view of a further variant of an optoelectronic lighting device according to the invention;

FIG. 9 shows a top view of the device of FIG. 8;

FIG. 10 shows a side cutaway view of a further variant of an optoelectronic lighting device according to the invention;

FIG. 11 shows a top view of the device of FIG. 10;

FIG. 12 shows a side cutaway view of still another variant of an optoelectronic lighting device according to the invention;

FIG. 13 shows a top view of the device of FIG. 12;

FIG. 14 shows a side cutaway view of still another variant of an optoelectronic lighting device according to the invention; and

FIG. 15 shows a top view of the device of FIG. 14.

### DETAILED DESCRIPTION OF ILLUSTRATIVE EMBODIMENTS

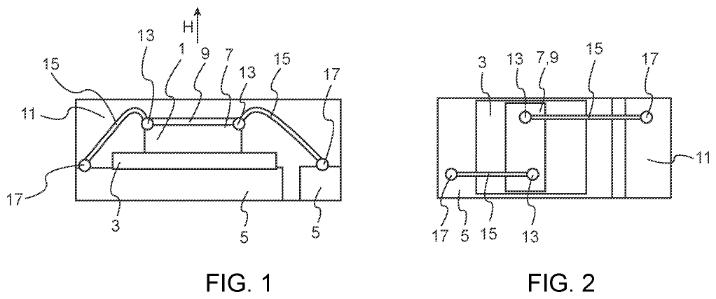

The optoelectronic lighting device shown in FIGS. 1 and 2 comprises an optoelectronic light source 1, such as an LED or a laser diode, for generating light, for example blue light, at least one converter 3 for generating converted light, for example infrared light, by converting the light provided by the light source 1, and a thermally conductive substrate 5. The converter 3 is arranged on the substrate 5 for better heat dissipation. The light source 1 is arranged above the converter 3, so that dissipation of the heat generated in the light source 1 can take place via the converter 3 and into the substrate 5.

Due to the improved heat dissipation, heat-related effects, such as “thermal quenching”, can be avoided or at least reduced. At least in making embodiments, higher currents through the light source 1, which result in a higher intensity of the provided light from the light source, hereinafter also referred to as pump light, thus do not lead to a decrease in the intensity of the converted light. By thermally connecting the converter 3 directly to the substrate 5, such a drop in intensity at higher intensities of the pump light can be avoided or at least reduced. Higher light powers with respect to the converted light are thus possible. Furthermore, a stable operation of the device can be achieved.

A mirror coating 9 is arranged directly on the upper side 7 of the light source 1. The mirror coating 9 can be in the form of a coating and, for example, as a Bragg mirror. The mirror coating 9 may be transparent to the converted light, so that radiation of the converted light can take place upwardly in the direction of a main radiation direction H. The mirror coating 9 can reflect the light provided by the light source so that this light is directed into the converter 3.

According to at least one embodiment of the invention, the term “transparent” or the term “transparency” may mean a transmittance of at least 50%, 60%, 70%, 80%, 90%, 95%, 98%, or 99% with respect to an incident light intensity.

According to at least one embodiment of the invention, the term “reflect” or the term “reflectivity” may mean a reflectivity of at least 50%, 60%, 70%, 80%, 90%, 95%, 98%, or 99% with respect to an incident light intensity.

The light emission area for the converted light may correspond to the area of the top surface 7 of the light source 1. The remaining area of the top surface of the device may be covered by a housing wall (not shown). The device may further be enclosed by housing walls on the outer side surfaces and on the bottom surface (not shown). The optional enclosure may be a part of the device in this regard.

The device may include an encapsulation 11 surrounding the converter 3 and the light source 1. In particular, the encapsulation 11 may fill a remaining volume between the substrate 5 and the light emitting surface. The encapsulation 11 may reflect the pump light. In particular, the encapsulation 11 may be highly reflective for the occurring wavelengths of the pump light.

To enable the light source 1 to be arranged directly on the converter 3, the two electrical contacts 13 of the light source 1 are arranged on the underside, which faces upwards in the representation according to FIG. 1. Via a respective bonding wire 15, a respective contact 13 is connected to an electrical contact 17 on the substrate 5.

The light source 1 can, for example, be an LED that is designed as a flip chip. The flip chip can be designed as a surface emitter that emits the pump light on its upper side. However, it can also be designed as a volume emitter, in which case light is emitted not only on the top side but also on the side surfaces.

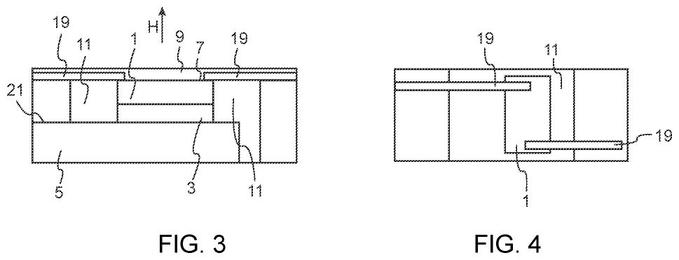

The variant of FIGS. 3 and 4 differs from the device described above in that the mirror coating 9 is formed as a layer which extends at least substantially over the entire length and width of the device. The mirror coating 9 is thereby arranged directly on the upper side 7 of the light source 1. The encapsulation 11 surrounds the light source 1 and the converter 3, but does not cover the light source 1 towards the top. The encapsulation 11 can thus be highly reflective for the pump light and the converted light, whereby an improvement of the coupling out upwards along the light emission direction H is achieved.

In the variant of FIGS. 3 and 4, planar contacts 19 are provided instead of bonding wires, which run in a plane parallel to the planar top surface 21 of the substrate 5 and connect the electrical contacts of the light source 1 to electrical contacts of a power supply located further out in the same plane.

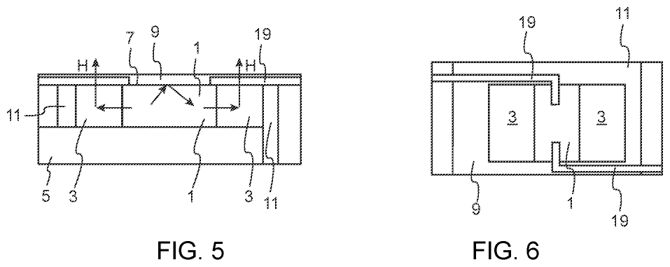

In the variant of FIGS. 5 and 6, the optoelectronic lighting device comprises an optoelectronic light source 1 for generating pump light and two converters 3 for generating converted light by converting the pump light. The light source 1 is arranged between the two converters 3. In this case, a respective longitudinal side of the light source 1 contacts a longitudinal side of a respective converter 3. For better heat dissipation, the converters 3 and the light source 1 are each arranged directly on a thermally conductive substrate 5. Thermal effects, such as “thermal quenching”, which negatively affect the conversion of light, can thus be reduced or avoided.

Furthermore, a mirror coating 9 is arranged directly on the upper side 7 of the light source 1. The mirror coating 9 can be in the form of a coating and, for example, as a Bragg mirror. The mirror coating 9 can be transparent to the converted light, so that radiation of the converted light can take place upwardly in the direction of the main radiation direction H. Since two converters 3 are provided, the radiation of converted light from each converter 3 is upward, as indicated by the respective main radiation direction H shown.

In the variant of FIGS. 5 and 6, planar contacts 19 are again provided which run in a plane parallel to the planar top surface 21 of the substrate 5 and which connect the electrical contacts of the light source 1 to electrical contacts of a power supply located further out in the same plane.

An encapsulation 11 surrounds the light source 1 and the converters 3. The encapsulation 11 may be highly reflective to the pump light and the converted light, thereby improving the upward coupling out.

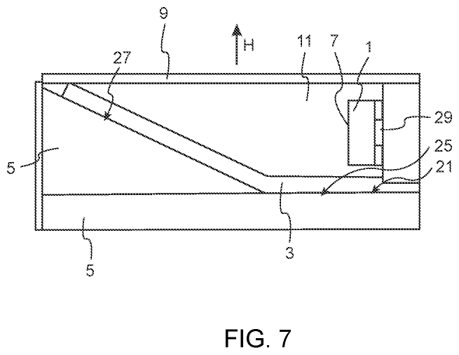

The variant of an optoelectronic lighting device shown in FIG. 7 comprises an optoelectronic light source 1 for generating pump light, a converter 3 for generating converted light by converting the pump light, and thermally conductive substrate 5. The converter 3 is again arranged on the substrate 5 for better heat dissipation, and the light source 1 is arranged laterally above the converter 3.

As FIG. 7 shows, the upper surface of the substrate 3 on which the converter 3 is arranged is divided into a flat region 25 and a rising region 27 adjoining the flat region 25. The rising region 27 thereby forms a ramp facing the upper side 7 of the light source 1. By this arrangement, the converter 1 can be particularly well irradiated with pump light, and converted light can be particularly well reflected upwardly by means of the rising region 27 of the substrate 5 and radiated over the upper side of the device along the main radiation direction H. The substrate 5 may thereby comprise a high reflectivity for the converted light and for the pump light. An encapsulation 11 filling the volume between converter 3 and light source 1 is preferably designed to be transparent, both for converted light and for pump light.

As shown, the top surface 7 of the light source 1 is oriented perpendicular to the top surface 21 of the flat region 25 of the substrate 5. The bottom surface of the light source 1 is attached to a wall 29 extending perpendicular to the flat region 25 of the substrate 5. The wall 29 may, for example, be a wall of a submount that provides electrical connections for the light source 1. Preferably, the light source 1 is formed as a flip chip so that the electrical contacts of the light source 1 face the wall 29.

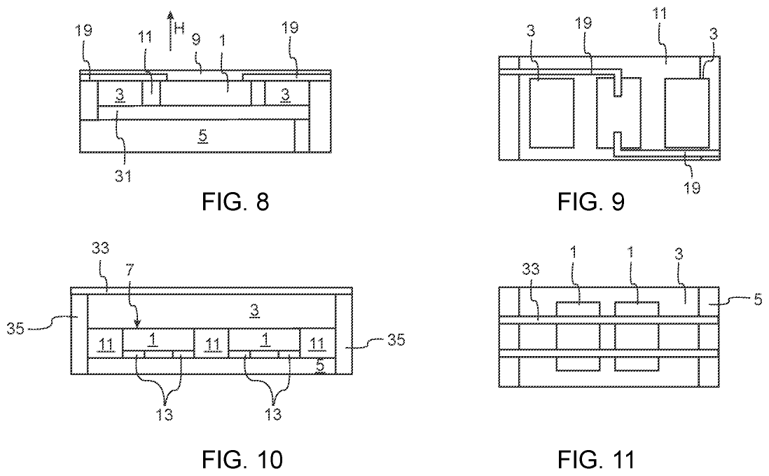

In the variant of FIGS. 8 and 9, the optoelectronic lighting device comprises an optoelectronic light source 1 for generating pump light, two converters 3 for generating converted light by converting the pump light, and a thermally conductive substrate 5. The light source 1 is arranged laterally next to and between the two converters 3. Between the substrate 5 and the light source 1 and the two converters 3, a light-conducting layer 31, in particular with a grating structure, is formed to guide the pump light from the light source 1 to the converters 3.

A good dissipation of the heat generated in the converters 3 can be made possible via the light-conducting layer 31 and the substrate 5 underneath. Disturbing thermal effects in the converters 3 can thus be avoided or at least reduced. To improve the light conduction, an encapsulation 11 is provided between the light source 1 and the converters 3, which can be highly reflective for both the pump light and the converted light.

Planar contacts 19 may again be provided to power the light source 1, as previously described. In addition, an overhead mirror coating 9 may extend along the entire length and width of the device. The mirror coating 9 may reflect the pump light and be transparent to the converted light to allow light to be emitted upwardly along the main emitting direction H.

In the variant according to FIGS. 10 and 11, the optoelectronic lighting device shown comprises two optoelectronic light sources 1 for generating pump light, a converter 3 for generating converted light by converting the pump light, and a thermally conductive substrate 5. A heat-conducting layer 33 for dissipating heat from the converter 3 is provided above the converter 3, in particular directly above the converter 3. By means of the heat conductive layer 33, an efficient dissipation of the heat generated in the converter 3 can be achieved. The heat conduction layer 33 is designed as a transparent layer so that an emission of converted light through the heat conduction layer 33 upwards out of the device is possible.

The light sources 1 are arranged on the substrate 5 and are designed as flip chips so that their electrical contacts 13 point downward and can be connected to contact points on the substrate 5 that are not shown.

The upper sides 7 of the light sources 1 can be flat, as shown, and the converter 3 is arranged directly on the flat upper sides 7. Direct coupling of the light generated by the light source 1 into the respective converter 3 can thus be achieved. The light source 1 is preferably designed as a surface emitter for this purpose.

An encapsulation 11 surrounds the light sources 1 and the bottom of the converter 3. The encapsulation 11 can thereby reflect the converted light and the pump light.

The heat-conducting layer 33 is in thermal contact at its respective outer edge with a housing wall 35 of the device. A build-up of heat in the heat-conducting layer 33 can thus be avoided. In addition, excess heat can be dissipated via the housing wall 35.

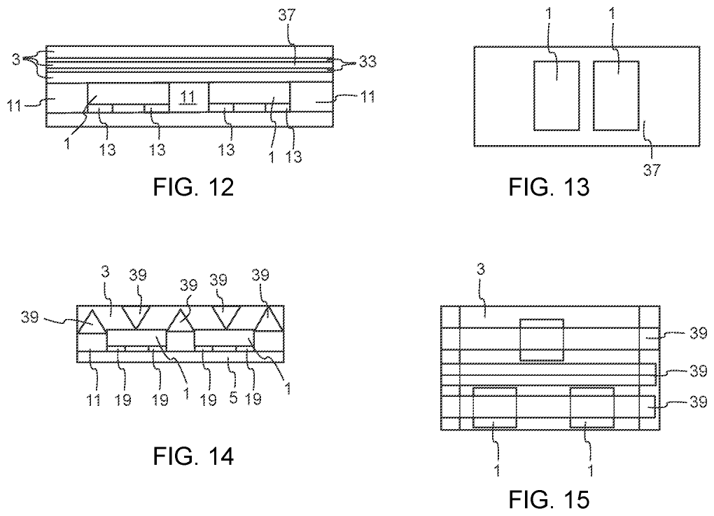

The variant of an optoelectronic lighting device shown in FIGS. 12 and 13 comprises two optoelectronic light sources 1 for generating pump light, at least one converter 3 for generating converted light by converting the pump light, and a thermally conductive substrate 5. The converter 3 is designed in the form of a multilayer structure 37. Thereby, a plurality of transparent thermal conductive layers 33 are arranged in the converter 3 for dissipating heat from the converter 3. Undesirable thermal effects in the converter 3 can thus be avoided or at least reduced.

The variant of an optoelectronic lighting device shown in FIGS. 14 and 15 comprises two optoelectronic light sources 1 for generating pump light, a converter 3 for generating converted light by converting the pump light, and a thermally conductive substrate 5. A number of non-transparent heat-conducting elements 39 are arranged in the converter 3 for dissipating heat from the converter 3. The heat conducting elements 39 can also avoid or at least reduce undesirable thermal effects in the converter 3.

A respective heat conducting element 39 may project through the converter 3 as viewed in a height direction, the height direction being perpendicular to the top surface of the substrate. Efficient heat dissipation over the entire height of the converter 3 can thus be achieved.

A respective heat conducting element 39 may comprise a triangular cross-section. Due to the triangular cross-section, a respective element is particularly suitable as a reflector for the light provided by the light source and/or for the converted light.

A respective heat element 39 may be configured as an elongated rod-like element, preferably having a triangular cross-section, as shown. Such a heat conducting rod may be fully or partially immersed in the converter 3 to enable heat to be dissipated. Particularly preferred is an arrangement of several parallel, spaced-apart heat-conducting rods that are fully or partially immersed in the converter 3. Preferably, the thickness of the cross-section corresponds to the thickness of the converter 3.

A respective heat conducting element 39 may be made of a metal, such as copper, silver, or gold.

The converter 3 can be designed as a converter plate with, for example, a rectangular cross-section.

The light source 1 may be an LED or an LED chip. The light source 1 can also be an optoelectronic laser, such as a laser diode or a VCSEL.

1-20. (canceled)

21. An optoelectronic lighting device comprising:
at least one optoelectronic light source configured to generate light;
at least one converter configured to generate converted light by converting the light; and
a thermally conductive substrate,
wherein the converter is arranged on the substrate and the light source is arranged above the converter,
wherein a mirror coating is arranged on a side of the light source facing away from the converter,
wherein the mirror coating is configured to be transparent for the converted light and/or to reflect the light,
wherein an upper side of the substrate, on which the converter is arranged, comprises a flat region and a rising region adjoining the flat region, and
wherein the converter is located at least on the rising region.

22. The optoelectronic lighting device according to claim 21, wherein the mirror coating is formed as a layer extending at least substantially over an entire length and width of the device.

23. The optoelectronic lighting device according to claim 21,
wherein the light source comprises electrical contacts for power supply on one side only, and
wherein the electrical contacts are formed as planar contacts extending in a plane parallel to a substrate top surface, or
wherein the electrical contacts are formed as a bonding wire.

24. The optoelectronic lighting device according claim 21, further comprising:
an encapsulation extending circumferentially around the converter and/or the light source,
wherein the encapsulation reflects the converted light and/or the light.

25. The optoelectronic lighting device according to claim 21, in case the light source is arranged laterally next to the at least one converter on the substrate, at least two converters are provided and the light source is arranged between the two converters.

26. The optoelectronic lighting device according to claim 21, wherein the light source is arranged above the flat region and an upper side of the light source faces the rising region.

27. The optoelectronic lighting device according to claim 26, wherein the upper side of the light source is aligned perpendicular to a surface of the flat region of the substrate.

28. The optoelectronic lighting device according to claim 21, wherein the substrate has a high reflectivity for the converted light and/or for the light.

29. An optoelectronic lighting device comprising:
at least one optoelectronic light source configured to generate light;
at least one converter configured to generate converted light by converting the light; and
a thermally conductive substrate,
wherein the light source is arranged laterally next to the converter and a light-conducting layer with a grating structure is located between the substrate and the light source in order to guide the light to the converter.

30. The optoelectronic lighting device according to claim 29, wherein the light-conducting layer is arranged on the substrate and the converter and the light source are arranged on the light-conducting layer.

31. The optoelectronic lighting device according to claim 29,
wherein at least two converters are provided and the light source is arranged between the two converters,
wherein an encapsulation is arranged between the light source and a respective converter, and
wherein the encapsulation is configured to reflect the converted light and the light.

32. An optoelectronic lighting device comprising:
at least one optoelectronic light source configured to generate light;
at least one converter configured to generate converted light by converting the light;
a thermally conductive substrate; and
at least one heat-conducting layer arranged in a beam path of the light source on a side of the converter facing away from the light source, the at least one heat-conducting layer being configured to dissipate heat from the converter.

33. The optoelectronic lighting device according to claim 32,
wherein the light source is arranged on the substrate and the converter is arranged above the light source,
wherein the light source has electrical contacts for power supply on its lower side facing the substrate, and
wherein an upper side of the light source is flat and the converter is arranged directly on the upper side of the light source.

34. The optoelectronic lighting device according to claim 32, further comprising:
an encapsulation extending circumferentially around the light source and under the converter,
wherein the encapsulation is configured to reflect the converted light and the light.

35. The optoelectronic lighting device according to claim 32, wherein the heat conducting layer is in thermal contact at its outer edge with a housing wall of the device.

36. An optoelectronic lighting device comprising:
at least one optoelectronic light source configured to generate light;
at least one converter configured to generate converted light by converting the light;
a thermally conductive substrate; and
one or more transparent heat conducting layers arranged in the converter, the one or more transparent heat conducting layer configured to dissipate heat from the converter,
wherein an upper side of the substrate, on which the converter is arranged, comprises a flat region and a rising region adjoining the flat region, and
wherein the converter is arranged at least on the rising region.

37. An optoelectronic lighting device comprising:
at least one optoelectronic light source configured to generate light;
at least one converter configured to generate converted light by converting the light; and
a thermally conductive substrate,
wherein an upper side of the substrate, on which the converter is arranged, comprises a flat region and a rising region adjoining the flat region,
wherein the converter is arranged at least on the rising region, and
wherein at least one non-transparent heat conducting elements are arranged in the converter, the at least one non-transparent elements being configured to conduct heat away from the converter.

38. The optoelectronic lighting device according to claim 37, wherein a respective heat conducting element projects through the converter, as seen in a height direction, the height direction being perpendicular to a substrate top side.

39. The optoelectronic lighting device according to claim 37,
wherein a respective heat conducting element comprises a triangular cross-section, and/or
wherein a respective heat conducting element is formed as an elongated rod, and
wherein, several parallel heat conducting elements are fully or partially immersed in the converter.
